(19) United States
(12) Patent Application Publication
(10) Pub. No.: US 2026/0040798 A1
(43) Pub. Date: Feb. 5, 2026

(54) DISPLAY PANEL AND DISPLAY DEVICE

(71) Applicants: Hefei Visionox Technology Co., Ltd., Hefei (CN); VISIONOX TECHNOLOGY INC., Jiangsu (CN)

(72) Inventors: Liusong NI, Hefei (CN); Yuting FU, Hefei (CN); Yiming XIAO, Hefei (CN); Yi-Yu LAI, Hefei (CN); Lipeng GAO, Hefei (CN); Yuan YAO, Hefei (CN); Zhengkui DONG, Hefei (CN); Xuejing ZHU, Hefei (CN); Murong XUE, Hefei (CN); Haohan ZHANG, Hefei (CN); Zihan WANG, Hefei (CN); Zhenhai YUE, Hefei (CN); Bowen YANG, Hefei (CN)

(73) Assignees: Hefei Visionox Technology Co., Ltd., Hefei (CN); VISIONOX TECHNOLOGY INC., Jiangsu (CN)

(21) Appl. No.: 19/285,227

(22) Filed: Jul. 30, 2025

(30) Foreign Application Priority Data
Jul. 30, 2024 (CN) 202411043072.4

(51) Int. Cl. H10K 59/80; H10K 59/12; H10K 59/122

(52) U.S. Cl. CPC H10K 59/873; H10K 59/1201; H10K 59/122

(57) ABSTRACT

A display panel includes a substrate, an isolation structure, light-emitting units and an encapsulation layer. The isolation structure is disposed on a side of the substrate, and encloses and forms isolation openings. The light-emitting units are disposed on a side of the substrate facing the isolation structure. The encapsulation layer includes first encapsulation portions. The first encapsulation portion is located on a side of at least one light-emitting unit facing away from the substrate and covers a surface of the isolation structure facing at least one of the isolation opening. A first encapsulation portion includes a first sidewall located on a side of the isolation structure facing away from the substrate, and on the cross section in the thickness direction of the substrate, the angle between at least part of the first sidewall and the plane on which the substrate is located is less than or equal to 90°.

### CROSS-REFERENCE TO RELATED APPLICATION(S)

The present application claims priority to the Chinese Patent Application No. 202411043072.4, filed on Jul. 30, 2024, and the entire contents of the aforementioned application are hereby incorporated by reference in its entirety.

### TECHNICAL FIELD

The present application relates to the field of display technology and, in particular, to a display panel and a display device.

### BACKGROUND

Among existing display panels, organic light-emitting diode (OLED) panels have been widely applied due to the good display effects in terms of color and image quality.

### SUMMARY

The present application provides a display panel and a display device.

In a first aspect, a display panel is provided according to some embodiments of the present application. The display panel includes a substrate, an isolation structure, a plurality of light-emitting units and an encapsulation layer. The isolation structure is disposed on one side of the substrate, and encloses and forms a plurality of isolation openings. The plurality of light-emitting units are disposed on a side of the substrate facing the isolation structure. The encapsulation layer includes a plurality of first encapsulation portions. A first encapsulation portion is located on a side of at least one of the plurality of light-emitting units facing away from the substrate and covers a side surface of the isolation structure facing at least one of the plurality of isolation openings. On a cross section in a thickness direction of the substrate, a first encapsulation portion of the plurality of first encapsulation portions includes a first sidewall, and an angle between at least part of the first sidewall and a plane on which the substrate is located is less than or equal to 90°. In a second aspect, a display panel is provided according to the present application. The display panel includes a substrate, an isolation structure, a plurality of light-emitting units and an encapsulation layer. The isolation structure is disposed on one side of the substrate, and encloses and forms a plurality of isolation openings. The plurality of light-emitting units are disposed on a side of the substrate facing the isolation structure. The encapsulation layer includes a first encapsulation portion. The first encapsulation portion is located on a side of at least one of the plurality of light-emitting units facing away from the substrate and covers a surface of the isolation structure facing an isolation opening of the plurality of isolation openings. Within a cross section parallel to a thickness direction of the display panel and passing through a central axis of the isolation opening corresponding to the first encapsulation portion, a first sidewall of the first encapsulation portion includes point A and point B, where a distance from the point A to a plane on which the substrate is located is Ha, a distance from the point A to the central axis of the isolation opening corresponding to the first encapsulation portion is La, a distance from the point B to the plane on which the substrate is located is Hb, and a distance from the point B to the central axis of the isolation opening corresponding to the first encapsulation portion is Lb, where Ha≤Hb, and La≥Lb.

In a third aspect, a display device is provided according to one or more embodiments of the present application. The display device includes the display panel in any one of embodiments of the first aspect and the second aspect.

In a fourth aspect, a preparation method for a display panel is provided according to one or more embodiments of the present application. The preparation method for a display panel includes: providing a substrate; forming an isolation structure on the substrate, where the isolation structure encloses and forms a plurality of isolation openings; sequentially depositing a first light-emitting material layer, a first electrode material layer and a first encapsulation material layer; adjusting different etching rates to pattern the first encapsulation material layer to form a first encapsulation portion to enable an angle between at least part of a first sidewall of the first encapsulation portion and a plane on which the substrate is located to be each less than or equal to 90°; patterning the first electrode material layer and the first light-emitting material layer to form a light-emitting unit to enable the light-emitting unit to be exposed from an isolation opening of the plurality of isolation openings.

In the display panel provided in the embodiments of the present application, the encapsulation layer is provided and includes a plurality of encapsulation portions corresponding to the plurality of light-emitting units. The plurality of encapsulation portions includes the plurality of first encapsulation portions. Within the cross section parallel to the thickness direction, a cross-sectional figure formed by the first sidewall of the first encapsulation portion is inclined and forms the angle less than 90° from the plane on which the substrate is located.

### BRIEF DESCRIPTION OF DRAWINGS

Features, advantages, and technical effects of example embodiments of the present application are described below with reference to the drawings.

FIG. 1 is a diagram illustrating the structure of a display panel according to an embodiment of the present application.

FIG. 2 is a diagram illustrating the structure of a display panel according to another embodiment of the present application.

FIG. 3 is a diagram illustrating the structure of a display panel according to yet another embodiment of the present application.

FIG. 4 is a cross-sectional view of position A-A′ in FIG. 1.

FIG. 5 is another cross-sectional view of position A-A′ in FIG. 1.

FIG. 6 is an enlarged view of a partial structure of a cross-sectional view in FIG. 5.

FIG. 7 is an enlarged view of another partial structure of a cross-sectional view in FIG. 5.

FIG. 8 is yet another cross-sectional view of position A-A′ in FIG. 1.

FIG. 9 is still another cross-sectional view of position A-A′ in FIG. 1.

FIG. 10 is a diagram illustrating the structure of a display device according to an embodiment of the present application.

FIG. 11 is a flowchart of a preparation method for a display panel according to an embodiment of the present application.

FIG. 12 is a flowchart of a preparation method for a display panel according to another embodiment of the present application.

### DETAILED DESCRIPTION

OLED display panels are widely applied due to their superior display performance. During the processing, to prevent pixels manufactured in the previous batch from being affected by the processing of pixels in the next batch, the pixels in the previous batch first require encapsulation. In the existing manufacturing process, reliability problems often arise due to the interference between films and encapsulation layers in the subsequent process steps.

To solve the preceding problem, embodiments of the present application provide a display panel, a display device and a preparation method for a display panel. In the display panel, the shape structure of a patterned encapsulation layer is adjusted to ensure that films in the subsequent process can smoothly cover a preset position, thereby avoiding damage to pixels and improving the production yield and reliability of the display panel.

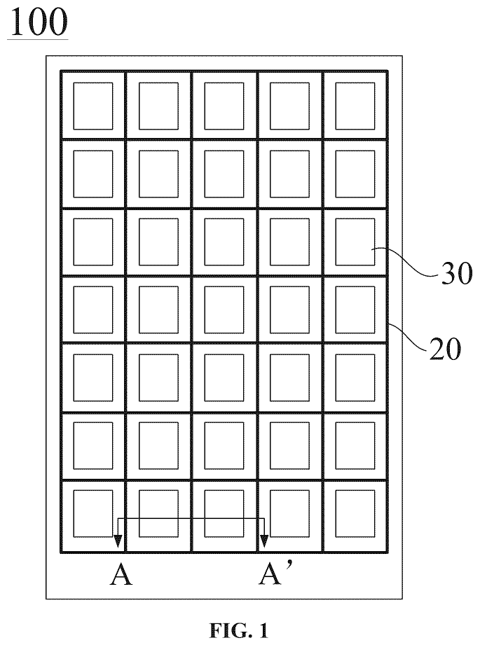

To better understand the present application, the display panel, the display device and the preparation method for a display panel provided in the embodiments of the present application are described in detail hereinafter with reference to FIGS. 1 to 11.

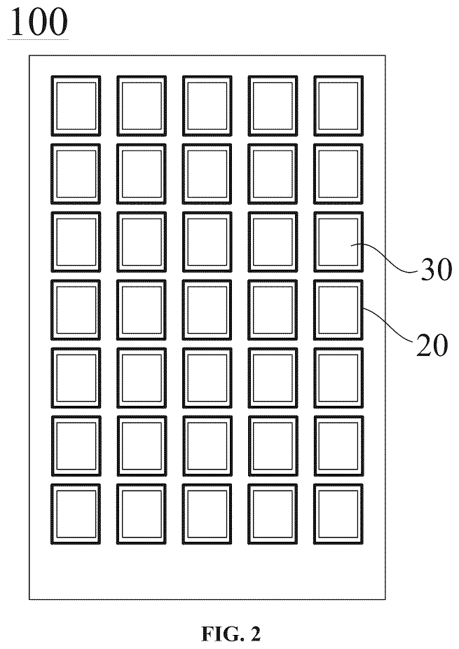

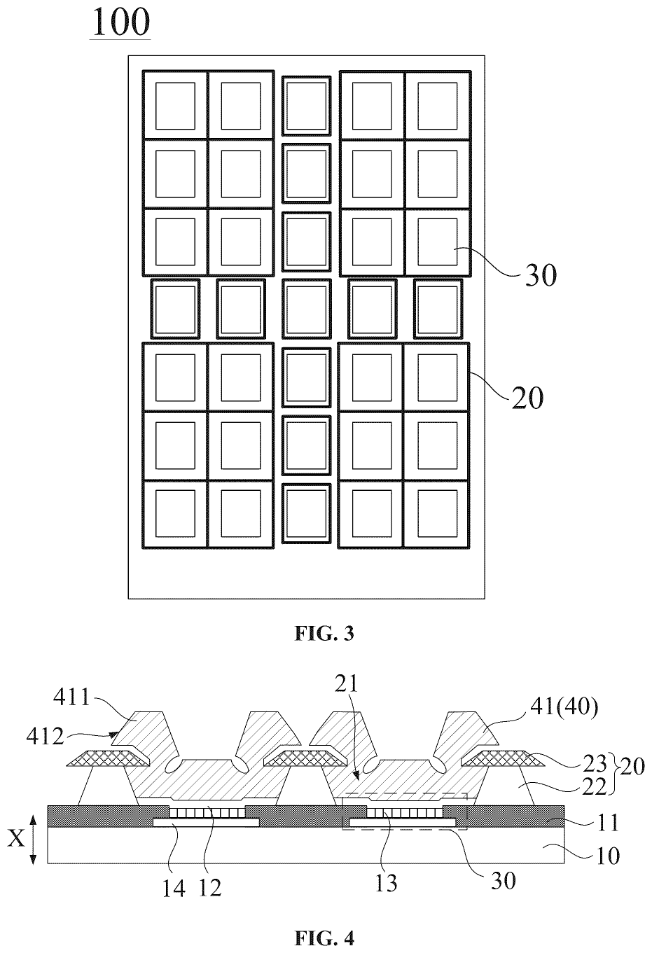

Referring to FIGS. 1 to 4, FIG. 1 is a diagram illustrating the structure of a display panel according to an embodiment of the present application; FIG. 2 is a diagram illustrating the structure of a display panel according to another embodiment of the present application; FIG. 3 is a diagram illustrating the structure of a display panel according to yet another embodiment of the present application; FIG. 4 is a cross-sectional view of position A-A′ in FIG. 1.

In a first aspect, a display panel 100 is provided according to one or more embodiments of the present application. Damage to light-emitting units of the display panel is prevented and the product yield of the display panel is improved. The display panel 100 includes a substrate 10, an isolation structure 20, multiple light-emitting units 30 and an encapsulation layer 40. The isolation structure 20 is disposed on a side of the substrate 10, and multiple isolation openings 21 are enclosed and formed by the isolation structure 20. The multiple light-emitting units 30 are disposed on a side of the substrate 10 facing the isolation structure 20, and at least part of a light-emitting unit 30 of the multiple light-emitting units 30 is exposed from an isolation opening 21 of the multiple isolation openings 21. The encapsulation layer 40 includes multiple encapsulation portions 41 spaced from each other. An encapsulation portion 41 is located on a side of a light-emitting unit 30 of the multiple light-emitting units 30 facing away from the substrate 10. The encapsulation portion 41 covers a surface of the isolation structure 20 facing at least one of the multiple isolation openings 21. The multiple encapsulation portions 41 include multiple first encapsulation portions 411. A first encapsulation portion 411 includes a first sidewall 412 located on a side of the isolation structure 20 facing away from the substrate 10. On the cross section in the thickness direction of the substrate 10, an angle between at least part of the first sidewall 412 and the plane on which the substrate 10 is located is less than or equal to 90°. The angle between the at least part of the first sidewall 412 and the plane on which the substrate 10 is located being less than or equal to 90° may be the angle between a part of the first sidewall 412 and the plane on which the substrate 10 is located being less than or equal to 90° or the angle between the entire first sidewall 412 and the plane on which the substrate 10 is located being less than or equal to 90°. In this manner, the multiple encapsulation portions partially form structural forms with a small upper portion and a large lower portion and a trapezoid-like cross-sectional shape so that a chamfered structure caused by the inward depression of the bottom of the encapsulation layer is prevented from interfering with the subsequent formation of pixel electrodes, thereby improving the production yield and reliability of the display panel.

Illustratively, a partial cross-sectional view of the display panel 100 is obtained by sectioning the display panel 100 through the cross section parallel to the thickness direction X, and the cross-sectional figure formed by the first encapsulation portion 411 is recorded as a first cross-sectional figure. The first cross-sectional figure includes an edge line formed by the first sidewall 412. An angle between the edge line and a straight line formed by the upper surface of the substrate 10 within the preceding cross section may be regarded as the angle formed between the first sidewall 412 and the plane on which the substrate 10 is located.

In the display panel 100 provided in the embodiments of the present application, the substrate 10 is provided with the isolation structure 20; at least parts of the multiple light-emitting units 30 are exposed from the multiple isolation openings 21 enclosed and formed by the isolation structure 20 respectively; a side of the multiple light-emitting units 30 facing away from the substrate 10 are provided with the encapsulation layer 40 for isolating water and oxygen, the encapsulation layer 40 includes the multiple encapsulation portions 41 corresponding to the multiple isolation openings 21, the multiple encapsulation portions 41 cover and encapsulate the multiple light-emitting units exposed from the multiple isolation openings 21, and at least part of these encapsulation portions 41 are first encapsulation portions 411 having specific inclined first sidewalls 412.

The first encapsulation portion 411 has the first sidewall 412 which is optionally disposed on the outer side of the first encapsulation portion 411, that is, the sidewall of an end portion on the outer periphery of the first encapsulation portion 411 is the first sidewall 412. A certain angle is formed between the first sidewall 412 and the plane on which the substrate 10 is located, and the angle may be optionally a right angle or an acute angle, that is, the first sidewall 412 of the first encapsulation portion 411 is inclined toward the central axis of an isolation opening 21 corresponding to the first encapsulation portion 411 in the direction facing away from the substrate so that the first encapsulation portion 411 can form a structural form with a narrow upper portion and a wide lower portion above the isolation structure. A portion of the first encapsulation portion 411 located above the isolation structure means the end portion of the slope-shaped first encapsulation portion 411. The central axis herein refers to the symmetry axis that makes the isolation opening centrally symmetrical from a top perspective, and the axis body optionally extends in the thickness direction X.

In some embodiments, the substrate 10 may also be provided with other structures having one or more layers, such as a pixel defining layer 11 and a second electrode 14 required for light emission. The second electrode 14 being an anode is used as an example for illustration in this embodiment. The pixel defining layer 11 may have a pixel opening 111.

The isolation structure 20 in the display panel 100 may be directly located on a side of the pixel defining layer 11 facing away from the substrate 10. The isolation structure 20 surrounds the pixel opening 111 and extends a certain dimension in the thickness direction X so that an isolation opening 21 is enclosed and formed by the isolation structure 20, where a side of the isolation opening 21 facing away from the substrate 10 is provided with a communication port and has a certain accommodation space. Optionally, multiple isolation openings 21 are in one-to-one correspondence with pixel openings 111, or an isolation opening 21 may correspond to multiple adjacent pixel openings 111. In the thickness direction of the substrate 10, the orthographic projection of an isolation opening 21 may cover the orthographic projection of the pixel opening 111, that is, the orthographic projection of a pixel opening 111 or multiple adjacent pixel openings on the substrate 10 is located within the contour range of the orthographic projection of an isolation opening 21 on the substrate, and the area of the isolation opening 21 is larger than the area of the pixel opening 111. The isolation structure 20 is disposed between some adjacent pixel openings 111, which can separate films of adjacent light-emitting units 30 and form independent pixel structures to prevent crosstalk between the adjacent light-emitting units 30 or oxidation failure caused by water vapor intrusion from spreading to the surrounding regions.

Specifically, the isolation structure 20 surrounds the pixel openings 111. Optionally, as shown in FIG. 1, the isolation structure 20 may be a mesh structure that continuously extends along intervals between the pixel openings 111 and is interconnected; or as shown in FIG. 2, the isolation structure 20 may be a ring structure corresponding to the pixel openings 111; or as shown in FIG. 3, the preceding two structures may be used together so that the isolation structure 20 may form a ring surrounding the multiple pixel openings 111, and the portion of the ring between the multiple pixel openings 111 is disposed as a mesh.

The display panel 100 includes the encapsulation layer 40. The encapsulation layer 40 includes the multiple encapsulation portions 41 corresponding to and covering the multiple light-emitting units 30. Each encapsulation portion 41 may extend from the upper surface of a respective light-emitting unit 30 along the first sidewall 412 of the isolation structure 20 to a position above the isolation structure 20 to form a tight encapsulation. The respective light-emitting unit 30 is exposed from a respective isolation opening 21, and each encapsulation portion 41 covers the respective light-emitting unit 30, the respective isolation opening 21 as well as the side surface of the isolation structure facing the respective isolation opening. Specifically, the multiple encapsulation portions 41 may be in one-to-one correspondence with the multiple light-emitting units 30, that is, an encapsulation portion 41 covers a light-emitting unit 30 and an isolation opening 21 corresponding to the light-emitting unit 30; or an encapsulation portion 41 may also correspond to multiple adjacent light-emitting units 30, that is, the encapsulation portion 41 covers the multiple light-emitting units 30 and isolation openings 21 corresponding to the multiple light-emitting units 30.

It is to be understood that in the existing display panels, to process light-emitting units 30 of different colors in batches, light-emitting units of a first color may be encapsulated after processing, and light-emitting units of a second color may be prepared later. In this process, existing encapsulation layers are prone to have structural forms with narrow bottoms after dry etching for patterning, resulting in films formed in the subsequent process being unable to cover the preset position and thereby causing damage to the films in the etching process and other process steps. As a result, the display effect is poor.

In this embodiment, by setting the first sidewalls 412 of the multiple encapsulation portions (that are, the multiple first encapsulation portions 411) corresponding to the multiple light-emitting elements prepared first to be inclined in the direction facing away from the substrate toward the central axes of corresponding isolation openings, the outer peripheral sides of the multiple first encapsulation portions 411 form slope surfaces, thereby making the multiple first encapsulation portions 411 as a whole have structural forms with a narrow upper portion and a wide lower portion. In preparing other films in the subsequent process steps, the other films are completely and reliably cover the outer peripheral sides of the multiple first encapsulation portions 411, and relatively complete protective films are formed above the multiple first encapsulation portions 411 to protect the multiple first encapsulation portions 411 and corresponding light-emitting units 30, so as to prevent first prepared light-emitting units from being damaged by the etching process and other processes in the formation process of later prepared light-emitting units, thereby effectively improving the reliability of the manufactured display panel.

In some embodiments, at least a part of the first encapsulation portion 411 extends to the side of the isolation structure 20 facing away from the substrate 10, and the first encapsulation portion 411 includes an extension portion 413 located on the side of the isolation structure 20 facing away from the substrate 10; the orthographic projection of the extension portion 413 on the substrate 10 is located within the range of the orthographic projection of the isolation structure 20 on the substrate 10.

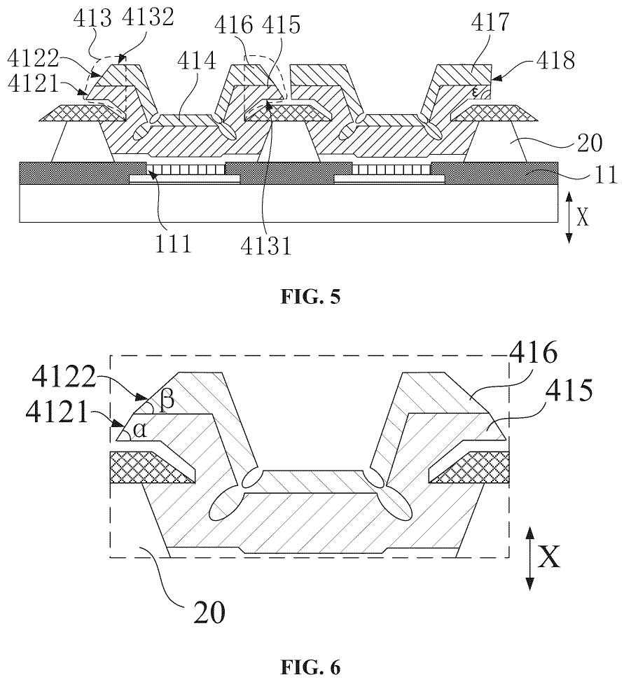

On this basis, the first encapsulation portion 411 may include a partial structure located within the isolation opening 21, that is, a base portion 414; the base portion 414 covers the side surface of the isolation structure 20 and the upper surface of a light-emitting unit 30 and is connected to the extension portion 413. For the first encapsulation portion 411 disposed between two adjacent isolation structures 20, the extension portion 413 is indicated by a dashed box shown in FIG. 5 and the base portion 414 refers to the remaining part of the first encapsulation portion 411 other than the extension portion 413.

The first encapsulation portion 411 protrudes from the isolation opening 21 and may extend from the isolation opening 21 to the peripheral side, extending to a portion above the isolation structure 20, so as to make the encapsulation more rigorous. Specifically, the portion of the first encapsulation portion 411 extending to the portion above the isolation structure 20 is the extension portion 413. In some embodiments, the extension portion 413 may abut against the top surface of the isolation structure 20, that is, the surface on one side facing away from the substrate 10, or the extension portion 413 may have a certain gap 419 with the isolation structure 20 in the thickness direction X.

The orthographic projection of the extension portion 413 on the substrate 10 is located within the range of the orthographic projection of the isolation structure 20 on the substrate 10, that is, the extension dimension of the extension portion 413 does not exceed the width of the isolation structure 20, thereby preventing the extension portion 413 from interfering with adjacent light-emitting units 30.

In some embodiments, in the thickness direction X, the orthographic projection of the extension portion 413 and the projection of the isolation structure 20 may have an overlapping region that may extend in the same direction as the isolation structure 20. On the cross section perpendicular to the extension direction of the isolation structure 20, the width of the extension portion 413 is less than half of the width of the isolation structure 20.

In some embodiments, the extension portion 413 includes a first sub-surface 4131 facing the substrate 10 and a second sub-surface 4132 facing away from the substrate 10, and the first sidewall 412 is connected to the first sub-surface 4131 and the second sub-surface 4132.

The extension portion 413 has two side surfaces opposite to each other in the thickness direction X. Of the two side surfaces, the contour of the orthographic projection of a side surface facing away from the isolation structure 20 may be located within the contour of the orthographic projection of the other side surface opposite to the side surface. Illustratively, the side surface of the extension portion 413 facing the substrate 10, that is, the side surface close to the isolation structure 20, is recorded as the first sub-surface 4131, and the side surface of the extension portion 413 opposite to the side surface and facing away from the substrate 10 is recorded as the second sub-surface 4132; the preceding first sidewall 412 may be connected between the two sub-surfaces.

In some embodiments, the angle between at least part of the first sidewall 412 and the first sub-surface 4131 is less than or equal to 90°. The angle between the first sidewall 412 of the extension portion 413 and the first sub-surface 4131 is also a right angle or an acute angle so that the cross section of the extension portion 413 is further ensured to have a structural form with a wide upper portion and a narrow lower portion, such as a trapezoid. The sidewall of the first encapsulation portion is inclined toward the corresponding isolation opening in the direction facing away from the substrate so that film subsequently disposed above the first encapsulation portion, especially an electrode material layer, can completely cover the first encapsulation portion, thereby improving the reliability of the display panel 100.

On the basis that the angle between the first sidewall 412 and the substrate 10 is the right angle or the acute angle, the angle between the first sidewall 412 and the first sub-surface 4131 may also be less than or equal to 90°. Specifically, the first sub-surface 4131 and the top surface of the isolation structure 20 optionally extend in the direction parallel or nearly parallel to the plane on which the substrate 10 is located.

In some embodiments, the orthographic projection of the second sub-surface 4132 of the extension portion 413 on the substrate 10 is located within the orthographic projection of the first sub-surface 4131 of the extension portion 413 on the substrate 10.

On the basis of the preceding inclined first sidewall 412, the second sub-surface 4132 may also have a relatively small area. Optionally, the outer side of the extension portion 413 may have an inwardly inclined first sidewall 412. Optionally, the inner side of the extension portion 413 facing the central axis of the isolation opening 21 may have an outwardly inclined first sidewall 412 or a first sidewall 412 perpendicular to the plane on which the substrate 10 is located so that the orthographic projection of the second sub-surface 4132 is located within the contour of the orthographic projection of the first sub-surface 4131, thereby ensuring that the extension portion 413 has the structural form with a narrow upper portion and a wide lower portion.

Exemplarily, the second sub-surface 4132 of the extension portion 413 may have a relatively small orthographic projection area, and the edge contour of the orthographic projection of the second sub-surface 4132 may be spaced from contours of the orthographic projections of adjacent encapsulation portions 41.

The angle between the first sidewall 412 of the extension portion 413 and the first sub-surface 4131 of the extension portion 413 is also a right angle or an acute angle, thereby ensuring that the first encapsulation portion 411 as a whole has the structural form with a narrow upper portion and a wide lower portion so that a subsequently evaporated layer structure completely and reliably covers the first sidewall 412 of the first encapsulation portion 411 during the processing, and the possibility that the films in the subsequent preparation process, especially the electrode material layer, does not form a continuous film structure on the first sidewall 412 of the first encapsulation portion 411 is reduced, thereby improving the overall yield and reliability of the display panel 100.

In some embodiments, the first encapsulation portion 411 includes at least one encapsulation sub-layer.

In some embodiments, according to different required encapsulation parameters, the encapsulation layer 40 may include at least one encapsulation sub-layer, and the first encapsulation portion 411 may correspondingly include one or more encapsulation sub-layers. It is to be understood that the number of encapsulation sub-layers in the first encapsulation portion 411 may be different from the total number of encapsulation sub-layers in the encapsulation layer 40 as a whole.

In some embodiments, referring to FIG. 4, the first encapsulation portion 411 includes an encapsulation sub-layer. The outer peripheral surface of the encapsulation sub-layer forms the first sidewall 412. The first sidewall 412 may be inclined by adjusting a patterning method or patterning parameters. The first encapsulation portion 411 consists of the encapsulation sub-layer so that the first encapsulation portion 411 is easy to process, thereby improving the overall processing efficiency of the display panel 100.

Referring to FIGS. 5 to 7, FIG. 5 is a cross-sectional view of position A-A′ in FIG. 1, FIG. 6 is an enlarged view of the partial structure of a cross-sectional view in FIG. 5, and FIG. 7 is an enlarged view of another partial structure of a cross-sectional view in FIG. 5.

In some embodiments, the first encapsulation portion 411 includes multiple encapsulation sub-layers stacked. The multiple encapsulation sub-layers stacked include adjacent first encapsulation sub-layer 415 and second encapsulation sub-layer 416. The second encapsulation sub-layer 416 is located on a side of the first encapsulation sub-layer 415 facing away from the substrate 10. It is to be noted that the multiple encapsulation sub-layers stacked include at least two encapsulation sub-layers, which may be two encapsulation sub-layers, three encapsulation sub-layers, or even more encapsulation sub-layers, which is not specifically limited. Any two adjacent encapsulation sub-layers are described in this embodiment.

In some embodiments, to conveniently enable the first encapsulation portion 411 to form a structural form with a narrow upper portion and a wide lower portion, the first encapsulation portion 411 may include multiple sub-layers stacked, and any two adjacent encapsulation sub-layers among the multiple encapsulation sub-layers stacked may specifically be the first encapsulation sub-layer 415 and the second encapsulation sub-layer 416 that are stacked; the second encapsulation sub-layer 416 is located on the side of the first encapsulation sub-layer 415 facing away from the substrate 10.

The multiple encapsulation sub-layers are disposed so that the inclination direction of the first sidewall 412 and the structural forms of the extension portion 413 and the first encapsulation portion are conveniently adjusted according to the difference in parameters such as etching rates and so that the display panel 100 is easy to process, thereby improving the processing efficiency.

In some embodiments, the first sidewall 412 includes a first sub-sidewall 4121 located in the first encapsulation sub-layer 415 and a second sub-sidewall 4122 located in the second encapsulation sub-layer 416; on the cross section in the thickness direction X of the substrate 10, the angle α between the first sub-sidewall 4121 and the plane on which the substrate 10 is located is less than or equal to 90°, and/or the angle β between the second sub-sidewall 4122 and the plane on which the substrate 10 is located is less than or equal to 90°. The first encapsulation sub-layer 415 includes a first surface 4141 facing the substrate 10 and a third surface 4143 facing away from the substrate 10, and the first sub-sidewall 4121 is connected to the first surface 4141 and the third surface 4143. The second encapsulation sub-layer 416 includes a fourth surface 4144 facing the substrate 10 and a second surface 4142 facing away from the substrate 10, and the second sub-sidewall 4122 is connected to the fourth surface 4144 and the second surface 4142. The angle α between the first sub-sidewall 4121 and the plane on which the substrate 10 is located may refer to the angle formed at the connection joint between the first surface 4141 and the first sub-sidewall 4121. The angle β between the second sub-sidewall 4122 and the plane on which the substrate 10 is located may refer to the angle formed at the connection joint between the fourth surface 4144 and the second sub-sidewall 4122. On the basis that the first encapsulation portion 411 includes the multiple encapsulation sub-layers stacked, the first sidewall 412 may correspondingly include the first sub-sidewall 4121 located in the first encapsulation sub-layer 415 and the second sub-sidewall 4122 located in the second encapsulation sub-layer 416; the angle between the at least part of the first sidewall 412 and the plane on which the substrate 10 is located being less than or equal to 90° may be the angle α between the first sub-sidewall 4121 and the plane on which the substrate 10 is located being less than or equal to 90°, or the angle β between the second sub-sidewall 4122 and the plane on which the substrate 10 is located being less than or equal to 90°, or the angles between the first sub-sidewall 4121 and the second sub-sidewall 4122 and the plane on which the substrate 10 is located being both less than or equal to 90°.

In some embodiments, the first sub-sidewall 4121 located on the side facing the isolation structure 20 may have the angle α less than or equal to 90° from the plane on which the substrate 10 is located to ensure that the bottom region of a side edge of the first encapsulation portion 411 facing the isolation structure 20 has a structural form with a narrow upper portion and a wide lower portion. Alternatively, the angle β between the second sub-sidewall 4122 and the plane on which the substrate 10 is located may also be less than or equal to 90°, which has the same function as the inclined first sub-sidewall 4121, and details are not repeated in the present application. Alternatively, the angles between the first sub-sidewall 4121 and the second sub-sidewall 4122 and the plane on which the substrate 10 is located are optionally each less than or equal to 90° so that the formed first sidewall 412 has a structural form that is inclined toward the inner side of the isolation opening 21 at all points.

In some embodiments, referring to FIG. 6, on the cross section in the thickness direction X of the substrate 10, the angle α between the first sub-sidewall 4121 and the plane on which the substrate 10 is located is not equal to the angle β between the second sub-sidewall 4122 and the plane on which the substrate 10 is located.

In the embodiment where the first encapsulation portion 411 includes the two encapsulation sub-layers stacked, the first sub-sidewall 4121 and the second sub-sidewall 4122 located in the two encapsulation sub-layers respectively optionally have the angles of different sizes from the plane on which the substrate 10 is located, and both of the two included angles are less than or equal to 90°.

Specifically, the relative size relationship between the angle α between the first sub-sidewall 4121 and the substrate 10 and the angle β between the second sub-sidewall 4122 and the substrate 10 is optionally designed according to process parameters such as etching. On the premise that the first sidewall 412 as a whole tends to be inclined in the direction facing the central axis of the isolation opening 21, the relative size relationship between the preceding two angles is not specifically limited in the present application.

The first sub-sidewall 4121 and the second sub-sidewall 4122 form different angles from the substrate 100 respectively so that the display panel 100 is adapted to different patterning methods, thereby reducing the processing difficulty and improving the processing efficiency.

In some embodiments, on the cross section in the thickness direction X of the substrate 10, the first sub-sidewall 4121 is not parallel to the second sub-sidewall 4122.

Similar to the preceding embodiments with the angles of different sizes, the first sub-sidewall 4121 and the second sub-sidewall 4122 may not be parallel to each other, that is, the extension directions of the first sub-sidewall 4121 and the second sub-sidewall 4122 intersect. The specific setting manners and effects are the same as those of the preceding embodiments, and details are not repeated in the present application.

In some embodiments, the orthographic projection of the second encapsulation sub-layer 416 on the substrate 10 is located within the contour of the orthographic projection of the first encapsulation sub-layer 415 on the substrate 10.

In some embodiments, the first encapsulation sub-layer 415 and the second encapsulation sub-layer 416 may be opposite to each other in the thickness direction X, and the orthographic projection of the first encapsulation sub-layer 415 completely covers the orthographic projection of the second encapsulation sub-layer 416 so as to avoid a chamfer in any edge region of the encapsulation portion 41, thereby further improving the reliability of the display panel 100.

In some embodiments, the first encapsulation portion 411 includes the extension portion 413 located on the side of the isolation structure 20 facing away from the substrate 10, the orthographic projection of the extension portion 413 on the substrate 10 is located within the orthographic projection of the isolation structure 20 on the substrate 10, and the orthographic projection of a portion of the first encapsulation sub-layer 415 located in the extension portion 413 on the substrate 10 covers the orthographic projection of a portion of the second encapsulation sub-layer 416 located in the extension portion 413 on the substrate 10.

As described in the preceding, in the embodiment with the presence of the extension portion 413, the orthographic projection of the extension portion 413 on the substrate 10 may be located within the orthographic projection of the isolation structure 20 on the substrate 10 to prevent the extension portion 413 from causing interference or short circuits to light-emitting units 30 in adjacent isolation openings 21.

On this basis, the extension portion 413 may include the first encapsulation sub-layer 415 and the second encapsulation sub-layer 416, and in the extension portion 413, the two sublayers may form a structure with a narrow upper portion and a wide lower portion, that is, the orthographic projection of a portion of the second encapsulation sub-layer 416 within the extension portion 413 is located within the orthographic projection of a portion of the first encapsulation sub-layer 415 within the extension portion 413 so that the extension portion has a shape with a small upper portion and a large lower portion, thereby improving the continuity of the subsequent films at the extension portion and reducing the possibility of damage to the first encapsulation portion and the corresponding light-emitting unit.

In some embodiments, the etching rate of the second encapsulation sub-layer 416 is greater than the etching rate of the first encapsulation sub-layer 415.

In some embodiments, the density of the second encapsulation sub-layer 416 is less than the density of the first encapsulation sub-layer 415.

In some embodiments, the refractive index of the second encapsulation sub-layer 416 is less than the refractive index of the first encapsulation sub-layer 415.

In some embodiments, the thickness of the first encapsulation sub-layer 415 is greater than the thickness of the second encapsulation sub-layer 416.

In some embodiments, to conveniently process the display panel 100 on the premise that the relative size relationship between the first encapsulation sub-layer 415 and the second encapsulation sub-layer 416 is maintained, the parameters of the two encapsulation sub-layers may be changed. Exemplarily, the second encapsulation sub-layer 416 may have a higher etching efficiency during etching, or the second encapsulation sub-layer 416 may have a sparser film structure, or the second encapsulation sub-layer 416 may have a lower refractive index so that the second encapsulation sub-layer 416 has a smaller orthographic projection area relative to the first encapsulation sub-layer 415 after processing. Alternatively, the thicknesses of the two encapsulation sub-layers may also be adjusted so that the first encapsulation sub-layer 415 located at the lower layer has a relatively large thickness and so that when an encapsulation sub-portion is formed by patterning, a morphology in which the at least part of the first sidewall of the first encapsulation portion is inclined toward the central axis of the isolation opening is formed more quickly, thereby improving the reliability of the display panel.

In some embodiments, in the thickness direction of the substrate, the first encapsulation sub-layer 415 includes the first surface 4141 facing the substrate 10 and the third surface 4143 facing away from the substrate 10, and the orthographic projection of the third surface 4143 on the substrate 10 is located within the contour of the orthographic projection of the first surface 4141 on the substrate 10. That is, the orthographic projection of an edge line of the third surface 4143 on the substrate 10 is located within the contour of the orthographic projection of an edge line of the first surface 4141 on the substrate 10; the first encapsulation sub-layer 415 has a trapezoidal shape with a large lower portion and a narrow upper portion. The subsequent films cover a side edge of the first encapsulation sub-layer 415 and form continuous films along the side edge of the first encapsulation sub-layer 415, thereby improving the overall yield and reliability of the display panel 100.

Similarly, in some embodiments, in the thickness direction of the substrate, the second encapsulation sub-layer 416 includes the fourth surface 4144 facing the substrate 10 and the second surface 4142 facing away from the substrate 10, and the orthographic projection of the second surface 4142 on the substrate 10 is located within the contour of the orthographic projection of the fourth surface 4144 on the substrate 10, that is, the orthographic projection of an edge line of the second surface 4142 on the substrate 10 is located within the contour of the orthographic projection of an edge line of the fourth surface 4144 on the substrate 10. That is, the second encapsulation sub-layer 416 has a trapezoidal shape with a large lower portion and a narrow upper portion. The subsequent films cover a side edge of the second encapsulation sub-layer 416 and form continuous films along the side edge of the second encapsulation sub-layer 416, thereby improving the overall yield and reliability of the display panel 100.

In some embodiments, the orthographic projection of the fourth surface 4144 on the substrate 10 is located within the contour of the orthographic projection of the third surface 4143 on the substrate 10, or the contour of the orthographic projection of the fourth surface 4144 on the substrate 10 coincides with the contour of the orthographic projection of the third surface 4143 on the substrate 10. That is, the orthographic projection of the edge line of the fourth surface 4144 on the substrate 10 is located within the contour of the orthographic projection of the edge line of the third surface 4143 on the substrate 10, or the contour of the orthographic projection of the edge line of the fourth surface 4144 on the substrate 10 coincides with the contour of the orthographic projection of the edge line of the third surface 4143 on the substrate 10. The connection joint between the first encapsulation sub-layer 415 and the second encapsulation sub-layer 416 is smoothly transitioned, and the first sidewall 412 of the first encapsulation portion 411 is prevented from having a concave structure, thereby preventing the subsequent films from being disconnected or cracked on the first sidewall 412 and further improving the overall yield and reliability of the display panel 100.

In some embodiments, referring to FIG. 4, the multiple encapsulation portions 41 include the multiple first encapsulation portions 411 covering all the light-emitting units 30. That is, the multiple encapsulation portions 41 corresponding to all the light-emitting units 30 are the multiple first encapsulation portions 411 respectively, and the multiple encapsulation portions 41 only include the multiple first encapsulation portions 411.

In some embodiments, the multiple encapsulation portions 41 in the display panel 100 may be the multiple first encapsulation portions 411 respectively. That is, the multiple encapsulation portions 41 have first sidewalls 412 respectively, and the angles between the first sidewalls 412 and the plane on which the substrate 10 is located are each less than or equal to 90°, thereby further improving the overall reliability of the display panel 100.

In some embodiments, in the embodiment where the multiple encapsulation portions 41 may be the multiple first encapsulation portions 411 respectively, the first encapsulation portion 411 may also include a first encapsulation sub-portion 4111 and a second encapsulation sub-portion 4112, and the angle formed between at least part of the first sidewall 412 of the first encapsulation sub-portion 4111 and the plane on which the substrate 10 is located is less than or equal to the angle formed between the second encapsulation sub-portion 4112 and the plane on which the substrate 10 is located.

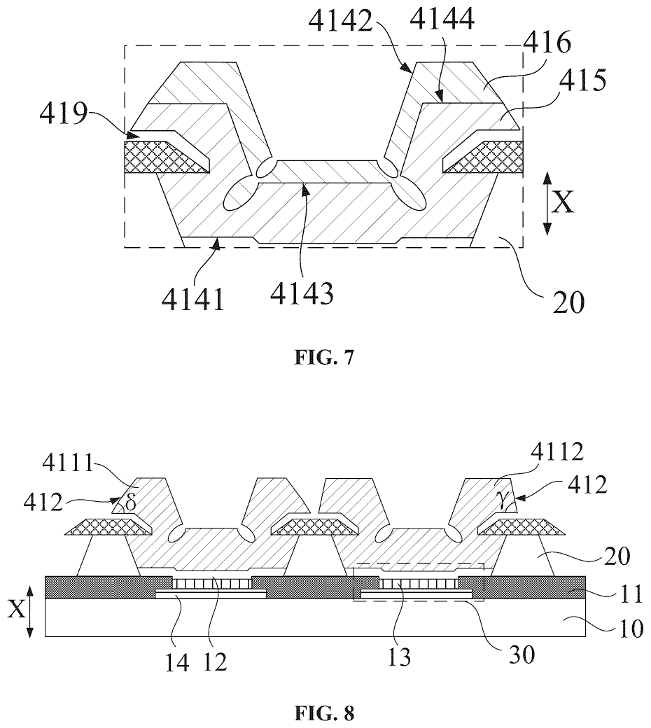

Referring to FIG. 8, FIG. 8 is yet another cross-sectional view of position A-A′ in FIG. 1. In the embodiment where the multiple encapsulation portions 41 are the multiple first encapsulation portions 411 and have the first sidewalls 412 respectively, these first encapsulation portions 411 optionally include two types of encapsulation sub-portions, that is, part of the multiple first encapsulation portions 411 are first encapsulation sub-portions 4111, and part of the multiple first encapsulation portions 411 are second encapsulation sub-portions 4112, and both of the two types of encapsulation sub-portions have first sidewalls 412. The angle between the first sidewall 412 of the first encapsulation sub-portion 4111 and the substrate 10 is recorded as the first angle δ, and the angle between the first sidewall 412 of the second encapsulation sub-portion 4112 and the substrate 10 is recorded as the second angle γ. The first angle δ and the second angle γ optionally have different angle sizes, and the first angle δ may be less than or equal to the second angle γ.

In some embodiments, referring to FIG. 5, the multiple encapsulation portions 41 further include a second encapsulation portion 417. The second encapsulation portion 417 includes a second sidewall 418. On the cross section in the thickness direction of the substrate 10, the angle between at least part of the second sidewall 418 and the plane on which the substrate 10 is located is greater than or equal to 90°.

Corresponding to the preceding structural form in which the multiple encapsulation portions 41 are the multiple first encapsulation portions 411 respectively, in this embodiment, the multiple encapsulation portions 41 of the display panel may also include both of the first encapsulation portion 411 and the second encapsulation portion 417; the second encapsulation portion 417 has the second sidewall 418 corresponding to the first sidewall 412; the angle ¿ between the second sidewall 418 and the plane on which the substrate 10 is located may be greater than or equal to 90°. That is, the second sidewall 418 tends to be inclined toward the outer side of an isolation opening 21 in the direction facing away from the substrate 10. It is to be noted that the multiple first encapsulation portions 411 may be encapsulation portions corresponding to the first prepared light-emitting units, and the second encapsulation portions 417 may be encapsulation portions corresponding to the later prepared light-emitting units; the morphology of the encapsulation portions corresponding to the later prepared light-emitting units is not limited, thereby improving the preparation efficiency of the display panel.

In some embodiments, in the embodiment where the multiple encapsulation portions 41 of the display panel may also include both of the first encapsulation portion 411 and the second encapsulation portion 417, the first encapsulation portion 411 further includes the first encapsulation sub-portion 4111 and the second encapsulation sub-portion 4112; on the cross-section in the thickness direction of the substrate 10, the angle formed between the at least part of the first sidewall 412 of the first encapsulation sub-portion 4111 and the plane on which the substrate 10 is located is less than or equal to the angle formed between at least part of the first sidewall 412 of the second encapsulation sub-portion 4112 and the plane on which the substrate 10 is located.

Similar to the preceding structural form in which each of the multiple encapsulation portions 41 is the first encapsulation portion 411, in the embodiment where the multiple encapsulation portions 41 include both of the first encapsulation portion 411 and the second encapsulation portion 417, the first encapsulation portion 411 still optionally includes the first encapsulation sub-portion 4111 and the second encapsulation sub-portion 4112, that is, the display panel includes the first encapsulation sub-portions 4111, the second encapsulation sub-portions 4112 and the second encapsulation portions 417, which has the similar function to the preceding embodiment, and details are not repeated in the present application.

In some embodiments, on the cross section perpendicular to the extension direction of the isolation structure 20, the width of the extension portion 413 is less than half of the width of the isolation structure 20.

The encapsulation layer 40 in the display panel 100 covers the sides of the multiple light-emitting units 30 facing away from the substrate 10 and may include the multiple encapsulation portions 41 corresponding to the multiple light-emitting units 30; the main bodies of these encapsulation portions 41 are disposed within the pixel openings 111 respectively and extend from the pixel openings 111 to the isolation structure 20 surrounding the pixel openings to cover at least part of the side surface of the isolation structure 20 and part of the top surface of the isolation structure 20; the first encapsulation portion 411 covering the top surface of the isolation structure 20 may only cover a partial region of the top surface, that is, the extension portion 413 of the first encapsulation portion 411 may only cover the partial region of the top surface.

In the thickness direction X of the display panel 100, the orthographic projection of each first encapsulation portion 411 and the orthographic projection of the isolation structure 20 have an overlapping region, and the width of the overlapping region, that is, the width of the extension portion 413, should be less than or equal to half of the width of the orthographic projection of the isolation structure 20. In some embodiments, the preceding width refers to the extension dimension in the direction parallel to the substrate 10 and perpendicular to the extension direction of the isolation structure 20, and the extension direction of the isolation structure 20 refers to the extension direction of part of the isolation structure 20 sandwiched between two light-emitting units 30 corresponding to adjacent encapsulation portions 41.

Exemplarily, in an embodiment where two sides of a certain section of the isolation structure 20 perpendicular to the extension direction of the certain section of the isolation structure are provided with encapsulation portions 41 respectively, the encapsulation portions 41 on the two sides extend toward the top surface of the isolation structure 20 separately and cover partial regions of the top surface respectively, and the two encapsulation portions 41 may be spaced from or connected to each other.

In some embodiments, a gap 419 is formed between the extension portion 413 of the first encapsulation portion 411 and the surface of the isolation structure 20 facing away from the substrate 10.

Illustratively, the gap 419 may be formed between the first encapsulation portion 411 and the surface of the isolation structure 20 facing away from the substrate 10 to limit the extension dimension of the first encapsulation portion 411 in the width direction of the isolation structure 20. Moreover, encapsulation portions 41 corresponding to adjacent light-emitting units 30 may also be separated from each other on the side of the isolation structure 20 facing away from the substrate 10, that is, the adjacent encapsulation portions 41 are spaced from each other on the side of the isolation structure 20 facing away from the substrate 10 to cut off the flow path of water vapor between the adjacent light-emitting units 30, thereby improving the encapsulation performance of the display panel 100.

In some embodiments, in the direction facing away from the substrate 10, a light-emitting unit 30 includes a light-emitting material layer 13 and a first electrode 12 that are sequentially stacked on the second electrode 14, and the isolation structure 20 includes a conductive structure electrically connected to the first electrode 12.

In some embodiments, each light-emitting unit 30 may be provided with the light-emitting material layer 13; and the first electrode 12 and the second electrode 14 that are located on two sides of the light-emitting material layer 13. The specific material of the light-emitting material layer 13 may be set according to the required emitted color of the multiple light-emitting units 30, and the electrodes on the two sides of the light-emitting material layer 13 may be an anode and a cathode respectively for light emission after an electrical signal is applied.

Further, second electrodes 14 of multiple light-emitting units 30 may be disconnected and separately controlled by the pixel defining layer 11, and first electrodes 12 of multiple light-emitting units 30 may cover the isolation structure 20 and may be electrically connected through the conductive structure included in the isolation structure 20 so that first electrodes 12 in the multiple adjacent light-emitting units 30 are applied with the same electrical signal. Exemplarily, each first electrode 12 may be a cathode, and a region of the isolation structure 20 contacting the first electrode 12 may be provided with a conductor extending to two sides in the width direction of the isolation structure 20 to achieve an electrical connection.

In some embodiments, the isolation structure 20 includes a first isolation portion 22 and a second isolation portion 23; the second isolation portion 23 is located on a side of the first isolation portion 22 facing away from the substrate 10; the orthographic projection of the first isolation portion 22 on the substrate 10 is located within the contour of the orthographic projection of the second isolation portion 23 on the substrate 10. In other embodiments, regarding the composition and material of the isolation structure (which is also called a partition structure), reference may also be made to related technical solutions recorded in patents or patent applications as such CN118251982A, 202410864269.8, PCT/CN2024/102783, PCT/CN2024/098217, PCT/CN2024/099419, PCT/CN2024/099072, and CN116685174A.

Referring to FIG. 4, the isolation structure 20 may include the first isolation portion 22 and the second isolation portion 23; the second isolation portion 23 is located on the side of the first isolation portion 22 facing away from the substrate 10; in the thickness direction X of the display panel 100, the area of the orthographic projection of the second isolation portion 23 is greater than the area of the orthographic projection of the first isolation portion 22, that is, in the thickness direction X of the display panel 100, the orthographic projection of the first isolation portion 22 is located within the contour of the orthographic projection of the second isolation portion 23. In this case, the isolation structure 20 forms a bottom concave structure with a narrow lower layer and a wide upper layer, that is, an undercut structure, which helps the films be cut off here to separate the adjacent light-emitting units 30, thereby preventing the crosstalk between the adjacent light-emitting units 30 or the oxidation failure caused by the water vapor intrusion from spreading to the surrounding regions.

In some embodiments, the substrate 10 includes the pixel defining layer 11, and the multiple pixel openings 111 are enclosed and formed by the pixel defining layer 11; the multiple light-emitting units 30 are located within the multiple pixel openings 111 respectively; the isolation structure 20 is disposed on the side of the pixel defining layer 11 facing away from the substrate 10; an isolation opening 21 of the multiple isolation openings 21 communicates with a respective pixel opening 111 of the multiple pixel openings 111.

As mentioned in the preceding, the display panel 100 may further include the pixel defining layer 11 for defining the positions and shapes of the multiple light-emitting units 30; the pixel defining layer has the multiple pixel openings 11; the multiple light-emitting units 30 are disposed within the multiple pixel openings 111 respectively. Optionally, the second electrodes 14 are partially disposed in a lower portion of the pixel defining layer 11 to facilitate the processing. Optionally, the multiple isolation openings 21 are in one-to-one correspondence with the multiple pixel openings 111, or an isolation opening 21 corresponds to multiple pixel openings 111. An isolation opening of the multiple isolation openings communicates with a pixel opening of the multiple pixel openings so that the encapsulation layer 40 covers the multiple light-emitting units 30.

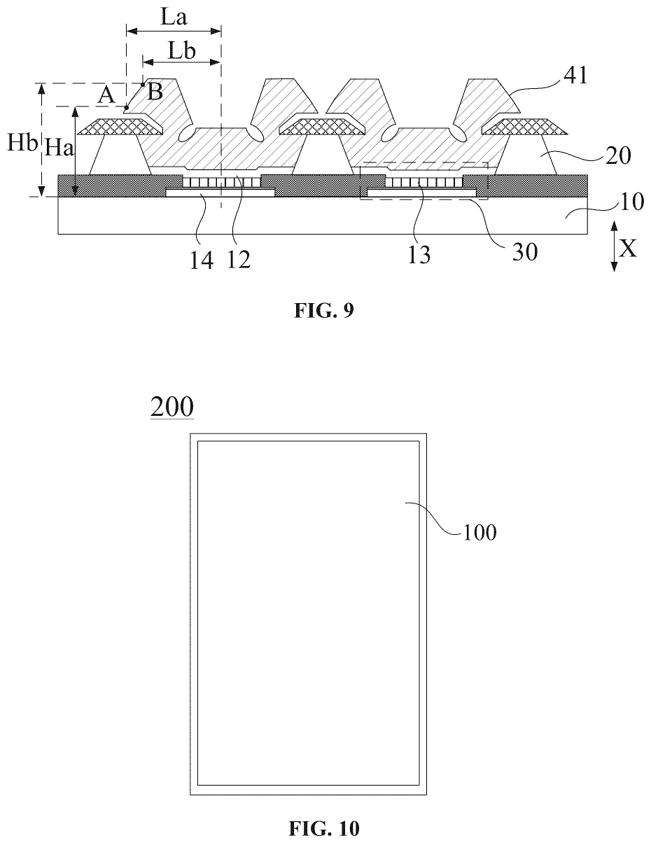

Referring to FIG. 9, FIG. 9 is still another cross-sectional view of position A-A′ in FIG. 1.

In a second aspect, a display panel 100 is provided according to one or more embodiments of the present application. The display panel 100 includes a substrate 10, an isolation structure 20, multiple light-emitting units 30 and an encapsulation layer 40. The isolation structure 20 is disposed on a side of the substrate 10, and multiple isolation openings 21 are enclosed and formed by the isolation structure 20. The multiple light-emitting units 30 are disposed on a side of the substrate 10 facing the isolation structure 20. At least part of a light-emitting unit 30 of the multiple light-emitting units 30 is exposed from an isolation opening 21 of the multiple isolation openings 21. The encapsulation layer 40 includes multiple encapsulation portions 41. An encapsulation portion 41 is located on a side of at least one of the multiple light-emitting units 30 facing away from the substrate 10 and covers a surface of the isolation structure 20 facing the multiple isolation openings 21. The multiple encapsulation portions 41 include a first encapsulation portion 411. Within the cross section parallel to the thickness direction of the display panel 100 and passing through the central axis of an isolation opening 21 corresponding to the first encapsulation portion 411, a first sidewall 412 of the first encapsulation portion 411 includes point A and point B. The distance from point A to the plane on which the substrate 10 is located is Ha, the distance from point A to the central axis of the isolation opening 21 corresponding to the first encapsulation portion 411 is La, the distance from point B to the plane on which the substrate 10 is located is Hb, and the distance from point B to the central axis of the isolation opening corresponding to the first encapsulation portion is Lb, where Ha≤Hb and La≥Lb.

In the display panel 100, the first encapsulation portion 411 may include a base portion 414 and an extension portion 413. The specific structures are similar to those in the preceding embodiments, and details are not repeated in the present application.

In some embodiments, the cross-sectional view of the display panel 100 is obtained by sectioning the display panel 100 through the cross section parallel to the thickness direction X; the first encapsulation portion 411 forms a first cross-sectional figure on the cross section, and the first cross-sectional figure has two edges opposite to each other in the thickness direction X, and an edge line formed by the first sidewall 412 is connected between the two edges.

On this basis, point A and point B are selected on the edge line. In the thickness direction X, the distance from point A to the substrate 10 is Ha, the distance from point B to the substrate 10 is Hb, and Ha≤Hb, that is, point A is located in a position closer to the substrate 10 relative to point B. Further, perpendicular lines are drawn from point A and point B to the central axis of the corresponding isolation opening, and the lengths of the formed perpendicular line sections are recorded as La and Lb respectively, where La≥Lb, that is, the distance from point A to the central axis is farther so that the extension portion 413 forms a structural form with a narrow upper portion and a wide lower portion, thereby enabling films processed and formed in the subsequent process steps to completely cover the first sidewall 412 and improving the reliability of the display panel 100.

In some embodiments, at least part of the first encapsulation portion 411 extends to a side of the isolation structure 20 facing away from the substrate 10, and the first encapsulation portion 411 includes the extension portion 413 located on the side of the isolation structure 20 facing away from the substrate 10; the orthographic projection of the extension portion 413 on the substrate 10 is located within the orthographic projection of the isolation structure 20 on the substrate 10; a side of the extension portion 413 facing away from the central axis of a light-emitting unit forms the first sidewall 412 of the first encapsulation portion 411.

The first encapsulation portion 411 may be formed with the extension portion 413 on the top surface of the isolation structure 20. The preceding first sidewall 412 may be located on the outer peripheral surface of the extension portion 413. The specific structural form is the same as the structural form of the first sidewall 412 in the first aspect, and details are not repeated in the present application.

Referring to FIG. 10, FIG. 10 is a diagram illustrating the structure of a display device 200 according to one or more embodiments of the present application. In a third aspect, a display device 200 is provided according to one or more embodiments of the present application. The display device 200 includes the display panel 100 in any one of the embodiments of the first aspect and the second aspect.

The display device 200 provided in the embodiments of the present application includes the display panel 100 in any one of the preceding embodiments. The display device 200 may be any product or component with a display function, such as a mobile phone, a tablet computer, a digital photo frame, or an electronic paper. The display device 200 provided in the embodiments of the present application has all the beneficial effects of the display panel 100 provided in the embodiment of the present application. For details, reference may be made to the specific description of the display panel 100 in the preceding embodiments, and the details are not repeated here in this embodiment.

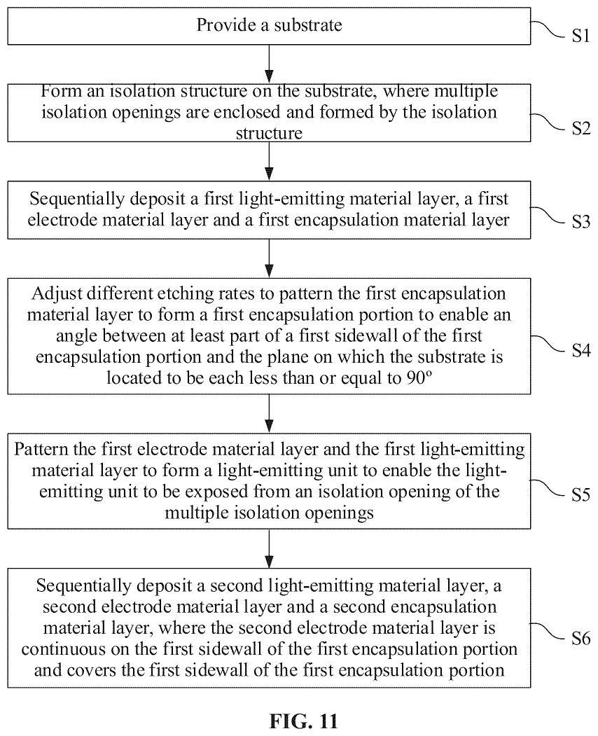

Referring to FIG. 11, FIG. 11 is a flowchart of a preparation method for a display panel 100 according to an embodiment of the present application. In a fourth aspect, one or more embodiments of the present application further provide a preparation method for a display panel 100. The preparation method includes the steps below.

In S1, a substrate 10 is provided.

In S2, an isolation structure 20 is formed on the substrate 10, where multiple isolation openings 21 are enclosed and formed by the isolation structure 20.

In S3, a first light-emitting material layer, a first electrode material layer and a first encapsulation material layer are deposited sequentially.

In S4, different etching rates are adjusted to pattern the first encapsulation material layer to form a first encapsulation portion to enable an angle between at least part of a first sidewall of the first encapsulation portion and the plane on which the substrate is located to be each less than or equal to 90°.

In S5, the first electrode material layer and the first light-emitting material layer are patterned to form multiple light-emitting units to enable the multiple light-emitting units to be exposed from the multiple isolation openings respectively.

The embodiment of the present application first provides the preparation method for a display panel 100. The preparation method first includes S1, that is, the substrate 10 is provided.

Illustratively, the substrate 10 provided in S1 may include a pixel defining layer 11. Multiple pixel openings 111 in the pixel defining layer 11 are spaced from each other, and these pixel openings 111 are used for defining the positions of to-be-prepared pixels. The multiple pixel openings 111 may be divided into different pixel openings 111 according to the emitted color of each light-emitting unit 30 in the display panel 100. In addition to the pixel defining layer 11, the substrate 10 may further include other structures having one or more layers and may include corresponding circuit wires for being electrically connected to the pixels and controlling the pixels to emit light.

In some embodiments, the substrate 10 may be provided with a second electrode 14 required to form a pixel and corresponding to a pixel opening 111 of the multiple pixel openings 111, and a least part of the second electrode 14 is exposed by the pixel opening 111 of multiple pixel openings 111 to form a light-emitting pixel with subsequent light-emitting materials and other electrodes.

In S2, the isolation structure 20 is prepared on the substrate 10. The isolation structure 20 may be staggered with the multiple pixel openings 111 and surround the multiple pixel openings 111. That is, the isolation structure 20 is disposed between adjacent to-be-formed pixels and may be used for separating films of the adjacent pixels and forming independent pixel structures to prevent crosstalk between the adjacent pixels or oxidation failure caused by water vapor intrusion from spreading to the surrounding regions. The multiple isolation openings 21 are enclosed and formed by the isolation structure 20. In some embodiments, these isolation openings 21 are in one-to-one correspondence with the multiple pixel openings 111 and communicate with the multiple pixel openings 111 in the thickness direction X.

In S3, the first light-emitting material layer, the first electrode material layer and the first encapsulation material layer are deposited sequentially on the same side of the preceding substrate 10, that is, the side on which the isolation structure 20 is disposed, to obtain a light-emitting material layer 13, a first electrode 12 and the first encapsulation portion 411 by patterning in the subsequent steps. When the first light-emitting material layer and the first electrode material layer are prepared, a manner such as evaporation may be used for processing, and the first light-emitting material layer may be a light-emitting material required for pixels of the same certain color in the display panel 100, such as any one of red, green, and blue colors, and any appropriate color may be selected.

In S4, the first encapsulation material layer is patterned to form the first encapsulation portion 411, and the angle between the at least part of the first sidewall 412 of the first encapsulation portion 411 located on the outer peripheral side and the plane on which the substrate 10 is located is less than or equal to 90°.

The step of patterning the first encapsulation material layer may be achieved in a manner such as etching. Specifically, in the process flow of patterning the first encapsulation material layer, a processing method should be adjusted accordingly so that the first encapsulation portion 411 obtained by patterning has the first sidewall 412 that is perpendicular to the substrate 10 or has an acute angle from the substrate 10, thereby forming a trapezoid-like structure with a narrow upper portion and a wide lower portion and so that the films in the subsequent process smoothly cover preset positions, thereby avoiding damage to pixels and improving the production yield and reliability of the display panel.

In S5, the first electrode material layer and the first light-emitting material layer are patterned to form the first electrode 12 and the light-emitting material layer 13 respectively and finally form the light-emitting unit 30 together with the other electrodes. That light-emitting unit 30 is exposed from the isolation opening 21 and covered by the first encapsulation portion 411.

In some embodiments, after S3 in which the first light-emitting material layer, the first electrode material layer and the first encapsulation material layer are deposited sequentially, the preparation method further includes a step below.

In S6, a second light-emitting material layer, a second electrode material layer and a second encapsulation material layer are deposited sequentially, where the second electrode material layer is continuous on the first sidewall 412 of the first encapsulation portion 411 and covers the first sidewall 412 of the first encapsulation portion 411.

In some embodiments, after the preparation related to the first encapsulation portion 411 is completed, the second light-emitting material layer, the second electrode material layer and the second encapsulation material layer may also be deposited on the substrate 10 for subsequently processing and forming structures of other light-emitting units 30, where the second light-emitting material layer optionally has an emitted color different from that of the first light-emitting material layer.

When being deposited, the second electrode material layer may cover the first sidewall 412 of the first encapsulation portion 411 so that the first encapsulation portion 411 has a structural form that is inclined toward the interior of a corresponding light-emitting unit 30 or perpendicular to the substrate 10 and so that the second electrode material layer smoothly covers the first sidewall 412 of the first encapsulation portion 411, thereby reducing the possibility of subsequent process steps such as patterning causing damage to the formed structures and improving the yield of the manufactured display panel 100.

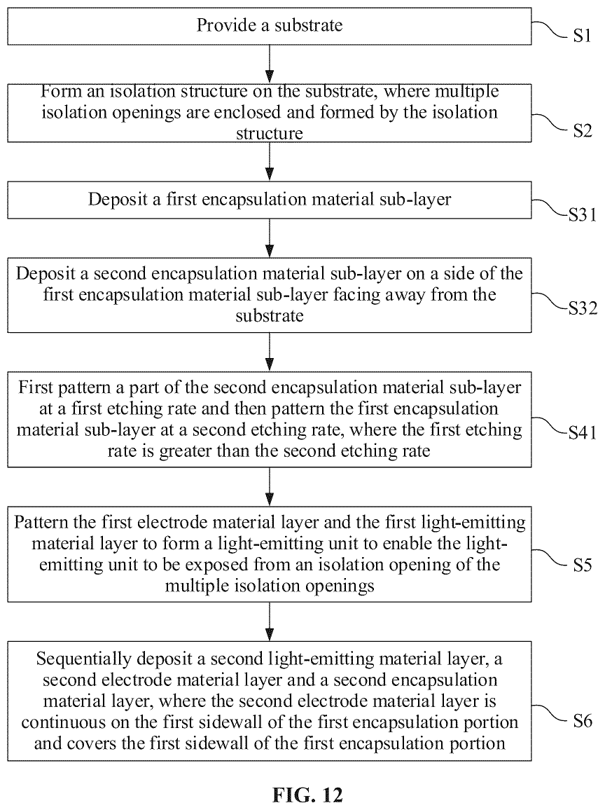

Referring to FIG. 12, FIG. 12 is a flowchart of a preparation method for a display panel according to another embodiment of the present application. In some embodiments, S3 in which the first encapsulation material layer is deposited includes the steps below.

In S31, a first encapsulation material sub-layer is deposited.

In S32, a second encapsulation material sub-layer is deposited on a side of the first encapsulation material sub-layer facing away from the substrate.

S4 in which the different etching rates are adjusted to pattern the first encapsulation material layer includes a step below.

In S41, a part of the second encapsulation material sub-layer is first patterned at a first etching rate, and the first encapsulation material sub-layer is then patterned at a second etching rate, where the first etching rate is greater than the second etching rate.

On the basis of the preceding processing method, the first encapsulation material layer may include a first encapsulation material sub-layer and a second encapsulation material sub-layer that are stacked. The two encapsulation material sub-layers are used for forming a first encapsulation sub-layer 415 and a second encapsulation sub-layer 416 by patterning respectively. According to the extension direction of the first sidewall 412, the second encapsulation sub-layer 416 optionally has an area less than or equal to that of the first encapsulation sub-layer 415.

When the preceding two encapsulation material sub-layers are etched, a substep etching manner is optionally adopted, and the etching rate of the second encapsulation material sub-layer is greater than the etching rate of the first encapsulation material sub-layer to ensure that a structural form in which the area of the second encapsulation sub-layer 416 is less than or equal to the area of the first encapsulation sub-layer 415 can be formed.

Alternatively, to improve the processing efficiency, the first encapsulation material sub-layer and the second encapsulation material sub-layer may also be processed in a synchronous etching manner. The two encapsulation material sub-layers are made of different materials or have structures with different densities so that the first encapsulation material sub-layer and the second encapsulation material sub-layer have different etching rates, thereby forming the second encapsulation sub-layer and the first encapsulation sub-layer with different widths in the same etching process to form the preceding first encapsulation portion 411 with a narrow upper portion and a wide lower portion.

What is claimed is:

1. A display panel, comprising:
a substrate;
an isolation structure, disposed on a side of the substrate and enclosing and forming a plurality of isolation openings;
a plurality of light-emitting units disposed on a side of the substrate facing the isolation structure; and
an encapsulation layer comprising a plurality of first encapsulation portions, wherein a first encapsulation portion of the plurality of first encapsulation portions is located on a side of at least one of the plurality of light-emitting units facing away from the substrate, and the first encapsulation portion covers a surface of the isolation structure facing at least one of the plurality of isolation openings,
wherein the first encapsulation portion comprises a first sidewall located on a side of the isolation structure facing away from the substrate, and on a cross section in a thickness direction of the substrate, an angle between at least part of the first sidewall and a plane on which the substrate is located is less than or equal to 90°.

2. The display panel of claim 1, wherein the first encapsulation portion comprises an extension portion located on the side of the isolation structure facing away from the substrate, and an orthographic projection of the extension portion on the substrate is located within an orthographic projection of the isolation structure on the substrate.

3. The display panel of claim 2, wherein the extension portion comprises a first sub-surface facing the substrate and a second sub-surface facing away from the substrate, and the first sidewall is connected to the first sub-surface and the second sub-surface; and
at least one of the following configurations is satisfied: an angle between the at least part of the first sidewall and the first sub-surface is less than or equal to 90°; and
an orthographic projection of the second sub-surface of the extension portion on the substrate is located within an orthographic projection of the first sub-surface of the extension portion on the substrate.

4. The display panel of claim 1, wherein
the first encapsulation portion comprises an encapsulation sub-layer; or
the first encapsulation portion comprises a plurality of stacked encapsulation sub-layers, wherein the plurality of stacked encapsulation sub-layers comprise a first encapsulation sub-layer and a second encapsulation sub-layer adjacent to the first encapsulation sub-layer, and the second encapsulation sub-layer is located on a side of the first encapsulation sub-layer facing away from the substrate.

5. The display panel of claim 4, wherein the first sidewall comprises a first sub-sidewall located in the first encapsulation sub-layer and a second sub-sidewall located in the second encapsulation sub-layer, and on the cross section in the thickness direction of the substrate;
wherein at least one of the following configurations is satisfied: an angle between the first sub-sidewall and the plane on which the substrate is located is less than or equal to 90°, and an angle between the second sub-sidewall and the plane on which the substrate is located is less than or equal to 90°;
on the cross section in the thickness direction of the substrate, the angle between the first sub-sidewall and the plane on which the substrate is located is not equal to the angle between the second sub-sidewall and the plane on which the substrate is located;
on the cross section in the thickness direction of the substrate, the first sub-sidewall is not parallel to the second sub-sidewall; and
an orthographic projection of the second encapsulation sub-layer on the substrate is located within a contour of an orthographic projection of the first encapsulation sub-layer on the substrate.

6. The display panel of claim 4, wherein the first encapsulation portion comprises an extension portion located on the side of the isolation structure facing away from the substrate, an orthographic projection of the extension portion on the substrate is located within an orthographic projection of the isolation structure on the substrate, and an orthographic projection of a portion of the second encapsulation sub-layer located in the extension portion on the substrate is located within a contour an orthographic projection of a portion of the first encapsulation sub-layer located in the extension portion on the substrate.

7. The display panel of claim 4, wherein at least one of the following configurations is satisfied:
an etching rate of the second encapsulation sub-layer is greater than an etching rate of the first encapsulation sub-layer;
a density of the second encapsulation sub-layer is less than a density of the first encapsulation sub-layer;
a refractive index of the second encapsulation sub-layer is less than a refractive index of the first encapsulation sub-layer; or
a thickness of the first encapsulation sub-layer is greater than a thickness of the second encapsulation sub-layer.

8. The display panel of claim 4, wherein in the thickness direction of the substrate, the first encapsulation sub-layer comprises a first surface facing the substrate and a third surface facing away from the substrate, and an orthographic projection of the third surface on the substrate is located within a contour of an orthographic projection of the first surface on the substrate.

9. The display panel of claim 4, wherein in the thickness direction of the substrate, the second encapsulation sub-layer comprises a fourth surface facing the substrate and a second surface facing away from the substrate, and an orthographic projection of the second surface on the substrate is located within a contour of an orthographic projection of the four surface on the substrate.

10. The display panel of claim 4, wherein in the thickness direction of the substrate, the first encapsulation sub-layer comprises a first surface facing the substrate and a third surface facing away from the substrate, and the second encapsulation sub-layer comprises a fourth surface facing the substrate and a second surface facing away from the substrate; and
an orthographic projection of the fourth surface on the substrate is located within a contour of an orthographic projection of the third surface on the substrate, or a contour of an orthographic projection of the fourth surface on the substrate coincides with a contour of an orthographic projection of the third surface on the substrate.

11. The display panel of claim 1, wherein the encapsulation layer comprises the plurality of first encapsulation portions covering all the plurality of light-emitting units.

12. The display panel of claim 11, wherein
the plurality of first encapsulation portions further comprise a first encapsulation sub-portion and a second encapsulation sub-portion, wherein an angle formed between at least part of the first sidewall of the first encapsulation sub-portion and the plane on which the substrate is located is less than or equal to an angle formed between at least part of the first sidewall of the second encapsulation sub-portion and the plane on which the substrate is located.

13. The display panel of claim 1, wherein the encapsulation layer further comprises a second encapsulation portion, and the second encapsulation portion is located on a side of the at least one of the plurality of light-emitting units facing away from the substrate and covers a side surface of the isolation structure facing an isolation opening of the plurality of isolation openings; and
the second encapsulation portion comprises a second sidewall located on the side of the isolation structure facing away from the substrate, and on the cross section in the thickness direction of the substrate, an angle between at least part of the second sidewall and the plane on which the substrate is located is greater than or equal to 90°.

14. The display panel of claim 2, wherein a gap is formed between the extension portion of the first encapsulation portion and a surface of the isolation structure facing away from the substrate; or
on a cross section perpendicular to an extension direction of the isolation structure, a width of the extension portion of the first encapsulation portion is less than half of a width of the isolation structure.

15. The display panel of claim 1, wherein at least one of the following configurations is satisfied:
in a direction facing away from the substrate, a light-emitting unit of the plurality of light-emitting units comprises a light-emitting material layer and a first electrode, wherein the light-emitting material layer and the first electrode are stacked sequentially, and the isolation structure comprises a conductive structure electrically connected to the first electrode;
the isolation structure comprises a first isolation portion and a second isolation portion, wherein the second isolation portion is located on a side of the first isolation portion facing away from the substrate, and an orthographic projection of the first isolation portion on the substrate is located within a contour of an orthographic projection of the second isolation portion on the substrate; or
the substrate comprises a pixel defining layer enclosing and forming a plurality of pixel openings, the plurality of light-emitting units are located in the plurality of pixel openings respectively, the isolation structure is disposed on a side of the pixel defining layer facing away from the substrate, and an isolation opening of the plurality of isolation openings communicate with a respective pixel opening of the plurality of pixel openings.

16. A display panel, comprising:
a substrate;
an isolation structure disposed on a side of the substrate and enclosing and forming a plurality of isolation openings;
a plurality of light-emitting units disposed on a side of the substrate facing the isolation structure; and
an encapsulation layer comprising a first encapsulation portion, wherein the first encapsulation portion is located on a side of at least one of the plurality of light-emitting units facing away from the substrate and covers a surface of the isolation structure facing an isolation opening of the plurality of isolation openings; and
within a cross section parallel to a thickness direction of the display panel and passing through a central axis of the isolation opening corresponding to the first encapsulation portion, a first sidewall of the first encapsulation portion comprises point A and point B;
wherein a distance from the point A to a plane on which the substrate is located is Ha, a distance from the point A to the central axis of the isolation opening corresponding to the first encapsulation portion is La, a distance from the point B to the plane on which the substrate is located is Hb, and a distance from the point B to the central axis of the isolation opening corresponding to the first encapsulation portion is Lb, wherein Ha≤Hb, and La≥Lb.

17. The display panel of claim 16, wherein the first encapsulation portion comprises an extension portion located on a side of the isolation structure facing away from the substrate, an orthographic projection of the extension portion on the substrate is located within an orthographic projection of the isolation structure on the substrate, and a side of the extension portion facing away from the central axis of the corresponding isolation opening forms the first sidewall of the first encapsulation portion.

18. A preparation method for a display panel, comprising:
providing a substrate;
forming an isolation structure on the substrate, wherein the isolation structure encloses and forms a plurality of isolation openings;
sequentially depositing a first light-emitting material layer, a first electrode material layer and a first encapsulation material layer;
adjusting different etching rates to pattern the first encapsulation material layer to form a first encapsulation portion to enable an angle between at least part of a first sidewall of the first encapsulation portion and a plane on which the substrate is located to be each less than or equal to 90°; and
patterning the first electrode material layer and the first light-emitting material layer to form a light-emitting unit to enable the light-emitting unit to be exposed from an isolation opening of the plurality of isolation openings.

19. The preparation method for a display panel of claim 18, wherein after sequentially depositing the first light-emitting material layer, the first electrode material layer and the first encapsulation material layer, further comprising:
sequentially depositing a second light-emitting material layer, a second electrode material layer and a second encapsulation material layer, wherein the second electrode material layer is continuous on the first sidewall of the first encapsulation portion and covers the first sidewall of the first encapsulation portion.

20. The preparation method for a display panel of claim 18, wherein depositing the first encapsulation material layer comprises:
depositing a first encapsulation material sub-layer; and
depositing a second encapsulation material sub-layer on a side of the first encapsulation material sub-layer facing away from the substrate; and
wherein adjusting the different etching rates to pattern the first encapsulation material layer to form the plurality of first encapsulation portions comprises:
first patterning a part of the second encapsulation material sub-layer at a first etching rate and then patterning the first encapsulation material sub-layer at a second etching rate, wherein the first etching rate is greater than the second etching rate.
